(19) United States
(12) Patent Application Publication
(10) Pub. No.: US 2020/0373927 A1
(43) Pub. Date: Nov. 26, 2020

(54) Differential Alias-Locked Loop

(71) Applicants: Jinghang Liang, Beijing (US); Duncan George Elliott, Edmonton (CA)

(72) Inventors: Jinghang Liang, Beijing (US); Duncan George Elliott, Edmonton (CA)

(21) Appl. No.: 15/929,830

(22) Filed: May 25, 2020

Related U.S. Application Data
(60) Provisional application No. 62/853,042, filed on May 26, 2019.

(51) Int. Cl. H03L 7/093; H03L 7/091; H03L 7/197; H03L 7/099

(52) U.S. Cl. CPC H03L 7/093; H03L 7/099; H03L 7/1974; H03L 7/091

(57) ABSTRACT

A control system method and apparatus that minimizes the difference between multiple state-derived signals, with application to frequency synthesis, is described. Existing Alias-Locked Loops (ALLs) use digital samplers in the feedback path to achieve a wide frequency lock range for high speed frequency synthesis, at the cost of one additional reference clock, compared to a Phase-Locked Loop (PLL). We propose the differential alias-locked loop (D-ALL) circuit architecture which uses only one reference clock input. In this D-ALL synthesizer architecture, two frequencies are derived from the voltage-controlled oscillator (VCO) output and are compared as the two inputs to the phase frequency detector (PFD). In contrast, a PLL or an ALL has a reference clock as one PFD input and a frequency derived from the VCO output as the other PFD input.

### U.S. PATENTS CITED

Leendert Jan van den Berg and Duncan George Elliott, Alias-Locked Loop Frequency Synthesizer Using A Regenerative Sampling Latch, 2011, U.S. Pat. No. 7,936,192 B2

Amr N. Hafez and Mohamed I. Elmasry, Phase Locked Loop Using Sub-Sampling, 2002, U.S. Pat. No. 6,463,112.

Amr N. Hafez and Mohamed I. Elmasry, Phase Locked Loop Using Sub-Sampling, 2003, U.S. Pat. No. 6,614,866.

Shu; Guanghua, Liu; Frankie Y., Subsampling phase frequency detector for a divider-less phase-locked loop, 2019, U.S. Pat. No. 10,425,092.

### SCHOLARLY ARTICLES CITED

X. Gao, E. A. M. Klumperink, M. Bohsali and B. Nauta, “A Low Noise Sub-Sampling PLL in Which Divider Noise is Eliminated and PD/CP Noise is Not Multiplied by N²”, in IEEE journal of Solid-State Circuits, vol. 44, no. 12, pp. 3253-3263, December 2009.

T. Riley, M. Copeland, T. Kwasniewski, “Delta-sigma modulation in fractional-N frequency synthesis”, IEEE J. Solid-State Circuits, vol. 28, no. 5, pp. 553-559, May 1993.

E. Familier and I. Galton, “Second and Third-Order Noise Shaping Digital Quantizers for Low Phase Noise and Nonlinearity-Induced Spurious Tones in Fractional-N PLLs,” in IEEE Transactions on Circuits and Systems I: Regular Papers, vol. 63, no. 6, pp. 836-847, June 2016.

Z. Zong, P. Chen and R. B. Staszewski, “A Low-Noise Fractional-N Digital Frequency Synthesizer With Implicit Frequency Tripling for mm-Wave Applications,” in IEEE Journal of Solid-State Circuits, vol. 54, no. 3, pp. 755-767, March 2019.

Y. H. Choi, B. Kim, J. Y. Sim and H. J. Park, “A Phase-Interpolator-Based Fractional Counter for All-Digital Fractional-N Phase-Locked Loop,” in IEEE Transactions on Circuits and Systems II: Express Briefs, vol. 64, no. 3, pp. 249-253, March 2017.

A. Li; Y. Chao; X. Chen; L. Wu; H. C. Luong, “A Spur-and-Phase-Noise-Filtering Technique for Inductor-Less Fractional-N Injection-Locked PLLs,” in IEEE journal of Solid-State Circuits, vol. PP, no. 99, pp. 1-13, April 2017

Kan, T. K. K.; Leung, G. C. T.; Luong, H. C., “A 2 V 1.8 GHz fully integrated CMOS dual-loop frequency synthesizer,” Solid-State Circuits, IEEE Journal of, vol. 37, no. 8, pp. 1012, 1020, August 2002

W. S. T. Yan and H. C. Luong, “A 2-V 900-MHz Monolithic CMOS Dual-Loop Frequency Synthesizer for GSM Receivers,” IEEE Journal of Solid-State Circuits, vol. 36, no. 2, pp. 204-216, February 2001.

Chan, P. Y.; Rofougaran, A.; Ahmed, K. A.; Abidi, A. A., “A Highly Linear 1-GHz CMOS Downconversion Mixer,” Solid-State Circuits Conference, 1993. ESSCIRC '93. Nineteenth European, vol. 1, no., pp. 210, 213, 22-24 Sep. 1993

A. N. Hafez and M. I. Elmasry, “A low power monolithic subsampled phase-locked loop architecture for wireless transceivers”, Circuits and Systems, 1999. ISCAS '99. Proceedings of the 1999 IEEE International Symposium on, pp. 549-552 vol. 2, July 1999

L. van den Berg and D. G. Elliott, “An alias-locked loop frequency synthesis architecture”, Circuits and Systems, 2008. ISCAS 2008. IEEE International Symposium, pp. 1536-1539, 18-21 May. 2008.

J. Liang and D. G. Elliott, “Coresidual alias-locked loops,” 2016 IEEE International Symposium on Circuits and Systems (ISCAS), Montreal, Q C, 2016, pp. 9-12.

J. Liang, Z. Zhou, J. Han and D. G. Elliott, “A 6.0-13.5 GHz Alias-Locked Loop Frequency Synthesizer in 130 nm CMOS”, IEEE Transactions on Circuits and Systems I, vol. 60, no. 1, pp. 108-115, 2013.

J. Lee, M. Liu and H. Wang, “A 75-GHz Phase-Locked Loop in 90-nm CMOS Technology,” in IEEE Journal of Solid-State Circuits, vol. 43, no. 6, pp. 1414-1426, June 2008.

Farjadrad R, Dally W j, Ng H, et al. “A low-power multiplying DLL for low-jitter multigigahertz clock generation in highly integrated digital chips”. IEEE Journal of Solid-state Circuits, 2002, 37(12): 1804-1812.

Elshazly A, Inti R, Young B, et al. “Clock Multiplication Techniques Using Digital Multiplying Delay-Locked Loops”. IEEE Journal of Solid-state Circuits, 2013, 48(6): 1416-1428.

Zhang X, Zhou X, Daryoush A S, et al. “A theoretical and experimental study of the noise behavior of subharmonically injection locked local oscillators”. IEEE Transactions on Microwave Theory and Techniques, 1992, 40(5): 895-902.

Raczkowski K, Markulic N, Hershberg B P, et al. “A 9.2-12.7 GHz Wideband Fractional-N Subsampling PLL in 28 nm CMOS With 280 fs RMS jitter”. IEEE journal of Solid-state Circuits, 2015, 50(5): 1203-1213.

Siriburanon T, Ueno T, Kimura K, et al. “A 60-GHz sub-sampling frequency synthesizer using sub-harmonic injection-locked quadrature oscillators”. IEEE Radio Frequency Integrated Circuits Symposium, 2014: pp. 105-108.

J. Cheng, N. Qi, P. Chiang and A. Natarajan, “A 1.3 mW 0.6V WBAN-Compatible Sub-Sampling PSK Receiver in 65 nm CMOS”, Solid-State Circuits Conference Digest of Technical Papers, 2014. ISSCC 2014. IEEE International, pp. 168-169, 8-12 Feb. 2014.

J. Sharma and H. Krishnaswamy, “A 2.4-GHz Reference-Sampling Phase-Locked Loop That Simultaneously Achieves Low-Noise and Low-Spur Performance,” in IEEE journal of Solid-State Circuits, vol. 54, no. 5, pp. 1407-1424, May 2019.

W. Wu et al., “A 28-nm 75-fsrms Analog Fractional-N Sampling PLL With a Highly Linear DTC Incorporating Background DTC Gain Calibration and Reference Clock Duty Cycle Correction,” in IEEE journal of Solid-State Circuits, vol. 54, no. 5, pp. 1254-1265, May 2019.

Chien J, Lu L. “Analysis and Design of Wideband Injection-Locked Ring Oscillators With Multiple-Input Injection”. IEEE journal of Solid-state Circuits, 2007, 42(9): 1906-1915.

Mesgarzadeh B, Alvandpour A. “First-Harmonic Injection-Locked Ring Oscillators”. IEEE Custom Integrated Circuits Conference (CICC), 2006: 733-736.

K. Hu, T. Jiang, J. Wang, F. O'Mahony and P. Chiang, “A 0.6 mW per Gb/s, 6.4-7.2 Gb/s Serial Link Receiver Using Local Injection-Locked Ring Oscillators in 90 nm CMOS”, IEEE J. Solid-State Circuits, vol. 45, no. 4, pp. 899-908, April 2010.

Jang S, Chuang Y, Lee S H, et al. “An Integrated 5-2.5-GHz Direct-Injection Locked Quadrature LC-VCO”. IEEE Microwave and Wireless Components Letters, 2007, 17(2): 142-144.

Y. Ding and K. K. O, “A 21-GHz 8-Modulus Prescaler and a 20-GHz Phase-Locked Loop Fabricated in 130-nm CMOS,” in IEEE journal of Solid-State Circuits, vol. 42, no. 6, pp. 1240-1249, June 2007.

### FIELD OF THE INVENTION

This invention is in the field of phase locked-loop based frequency synthesizers. More particularly, the present invention describes a PLL frequency synthesizer employing two feedback frequencies derived from the voltage-controlled oscillator output and compared as the two inputs to the phase frequency detector.

### BACKGROUND OF THE INVENTION

Phase-locked loops (PLLs) play an important role since they provide the timing basis in modern integrated circuits. A conventional integer-N PLL provides a channel spacing that is equal to the reference frequency, which results in a large division ratio and a small reference frequency. The small reference frequency limits the loop bandwidth and the large division ratio amplifies the phase noise from the charge pump (CP) and the phase frequency detector (PFD) by N² (where N is the division ratio).

To solve this problem, researchers proposed the fractional-N PLL architecture. A ΔΣ modulator is usually used in the feedback path to shape the quantization noise. Otherwise, novel techniques such as fractional-N counters based on phase interpolator or phase-noise-filtering based on phase-domain averaging are required to suppress the phase noise. Another solution is to use a mixer in the feedback path to down-convert the voltage-controlled oscillator (VCO) signal before feeding to the PFD. For instance, a dual loop architecture was proposed with a single sideband (SSB) mixer in the feedback path. An analog sample-and-hold circuit can be directly applied as a down-conversion mixer. Based on this observation, researchers have proposed another topology using an analog subsample-and-hold circuit as the down-conversion mixer in the feedback path. In all of these abovementioned mixer-based solutions, additional filters are usually required to filter out the undesired tones and this increases the complexity, adds additional cost, and reduces frequency range. For instance, a 6th-order Butterworth low-pass filter is used to filter out the harmonics. In the dual-loop architecture, however, the unwanted sidebands resulting from mismatches and non-linearities of the SSB mixing can be alleviated by placing the SSB mixer inside the main feedback loop.

The alias-locked loop (ALL) circuit architecture, which uses a digital sampler in the feedback path, was proposed. Compared to all the analog mixers, a digital sampler can directly down-convert and digitize the VCO signal without the need for filters. An ALL has several advantages including a wide frequency range of operation and savings in design cost. The disadvantage, however, is the demand for one extra reference clock compared to a PLL.

### BRIEF SUMMARY OF THE INVENTION

The present invention is a PLL-based frequency synthesizer that includes a phase detector, a loop filter, a tunable oscillator, and a feedback module with two or more feedback signals. One or more of these feedback signals operate at a reduced frequency generated from the oscillator signal, and the frequencies of these feedback signals having different slopes with respect to the oscillator frequency.

In some embodiments, the feedback module comprises one or more regenerative sampling latches incorporated to generate the feedback signals. The regenerative sampling latches operate as frequency reduction circuits by sampling the oscillator signal. The frequency of each regenerative sampling latch output signal averages to an alias frequency that is determined by the corresponding sampling signal frequency and oscillator frequency, respectively.

In some embodiments, the feedback module comprises only one regenerative sampling latch clocked by a separate sampling clock signal at frequencies lower than the oscillator frequency. Two or more latches are incorporated in cascade with the regenerative sampling latch, respectively. The clocks for the latches can be generated by dividing the sampling clock signal of the regenerative sampling latch, and the division ratios can be any positive number. In the case where the frequency dividers are programmable, the frequency of clocks for the latches are configurable, allowing a plurality of frequencies to be synthesized through configuration of the frequency dividers. The clocks for the latches can be generated by dividing the sampling clock signal of the regenerative sampling latch, and the division ratios can be any positive number. In the case where the frequency dividers are programmable, the frequency of clocks for the latches are configurable, allowing a plurality of frequencies to be synthesized through configuration of the frequency dividers.

In some embodiments, the feedback module comprises two or more regenerative sampling latch clocked by separate sampling clock signals at frequencies lower than the oscillator frequency. The sampling clock signals for the regenerative sampling latches can be generated by dividing the same clock signal. The division ratios can be any positive number. In the case where the frequency dividers are programmable, the frequency of clocks for the regenerative sampling latches are configurable, allowing a plurality of frequencies to be synthesized through configuration of the frequency dividers.

Two or more latches are incorporated in cascade with the regenerative sampling latch, respectively. The clocks for the latches can be generated by dividing the sampling clock signal of the regenerative sampling latch, and the division ratios can be any positive number. In the case where the frequency dividers are programmable, the frequency of clocks for the latches are configurable, allowing a plurality of frequencies to be synthesized through configuration of the frequency dividers. The clocks for the latches can be generated by dividing the sampling clock signal of the regenerative sampling latch, and the division ratios can be any positive number. In the case where the frequency dividers are programmable, the frequency of clocks for the latches are configurable, allowing a plurality of frequencies to be synthesized through configuration of the frequency dividers. The frequency dividers can be incorporated in cascade with the regenerative sampling latches to adjust the frequency and phase of the feedback signals. The division ratios can be any positive number. In the case where the frequency dividers are programmable, the frequency and phase of the feedback signals are configurable, allowing a plurality of frequencies to be synthesized through configuration of the frequency dividers.

The following drawings and description provide further details about the specific nature of the invention.

### BRIEF DESCRIPTION OF THE DRAWINGS

In the accompanying drawings:

FIG. 1 is a block diagram of a frequency synthesizer based on a phase-locked loop (PLL) architecture.

FIG. 2 is a block diagram of a frequency synthesizer based on an alias-locked loop (ALL) architecture.

FIG. 3 is a block diagram of a control system where one or more inputs to the system are controlled to minimize the difference between multiple signals generated from the system state. Specifically, the control system with more than one feedback signals can be used as a frequency synthesizer.

FIG. 4 shows a differential alias-locked loop (D-ALL) implementation of the frequency synthesizer shown in FIG. 3 to incorporate two feedback paths. The two feedback paths are implemented by two digital samplers. In some cases, additional dividers are used to provide further division.

FIG. 5 shows modification of the frequency synthesizer shown in FIG. 4 with only one digital sampler, or, another implementation of D-ALL with only one digital sampler. In some cases, additional dividers are used to provide further division.

FIG. 6 shows pseudo code for choosing parameters of a D-ALL.

FIG. 7 shows alias frequencies produced by a D-ALL.

FIG. 8 shows the alias frequencies and absolute value of alias frequencies of a D-ALL.

FIG. 9 shows transient simulations of a D-ALL synthesizing a 21.6 GHz signal.

### DETAILED DESCRIPTION OF THE INVENTION

Before a detailed description is given of frequency synthesis using a regenerative sampling latch in the feedback path of the phase-locked loop (PLL), it is to be understood that the present invention fits in what is effectively a prescribed arrangement of conventional analog and digital circuits and components, and not the details of such components. As such, the configuration of such circuits and components, and the manner in which they may be interfaced with other systems, circuits or components have, for the most part, been illustrated in block diagram format, showing only those details that are pertinent for the present invention, so as not to obscure the disclosure with details which will be readily apparent to those skilled in the art having the benefit of the description herein. Thus, the block diagram illustrations are primarily intended to show the major components of the frequency synthesizer in a conventional functional grouping, whereby the present invention may be more readily understood.

Digital sampler: a digital sampler is a circuit that samples a continuous or analog input signal with a clock signal and provides a digital output of the analog input as sampled around the time of the clock signal. A digital sampler can be implemented with a sense-amplifier style differential latch, a current mode logic (CML) latch, a CMOS digital logic latch or any other similar architectures.

Regenerative sampling latch: a digital sampler that explicitly has internal positive feedback that can amplify a signal close to its logic threshold to a definitive logic level.

Negative alias frequency: if when the frequency of the input of the sampler (or “the VCO frequency”) increases (decreases), the frequency of the sampler output (or “the alias frequency”) decreases (increases).

Slope: when the frequency of the input signal (or “the VCO frequency”) changes by Δx, the sampled output frequency changes (or “the alias frequency”) by Δy, then the slope is defined as Δy/Δx.

Latch: a circuit which retains whatever output state results from a momentary input signal until reset by another signal. Flipflops, including D-type flipflops, contain latches and are candidates to be used where we call for latches.

Mode-control module: a circuit module that can invert the sense of up and down of PFD output to change the loop polarity from positive feedback to negative feedback or vice versa.

This invention disclosed herein describes a method to build frequency synthesis circuits where two frequencies are derived from the voltage-controlled oscillator (VCO) output and are compared as the two inputs to the phase frequency detector (PFD).

### Locking Mechanisms Comparison

Both a phase-locked loop (PLL) and an alias-locked loop (ALL) compare the feedback signal with a fixed reference signal.

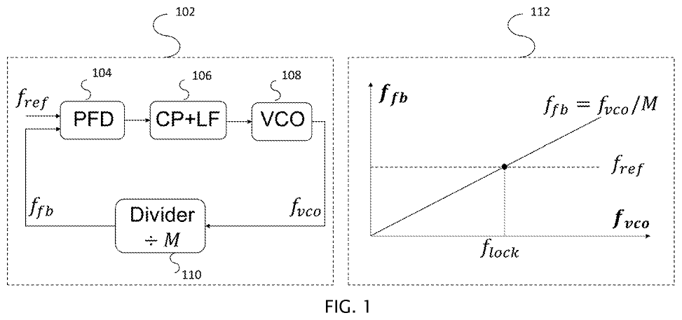

The block diagram 102 and locking mechanism 112 of a PLL are shown in FIG. 1. The VCO signal is first divided by a divider 110 to generate the feedback signal, and then the feedback signal is compared with reference clock by a PFD 104. The output of the PFD will then control the charge pump and loop filter 106 to tune the VCO 108.

As shown in FIG. 1 112, within a certain frequency range, the frequency of the feedback signal can be treated as a linear function of the VCO frequency. The slope of the linear function within a PLL is 1/M, where M is the division ratio of the feedback divider of a PLL.

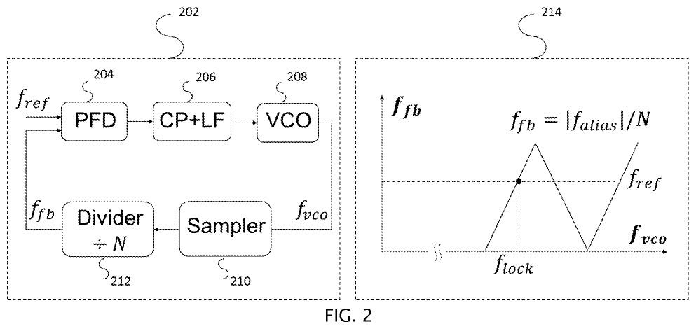

The block diagram 202 and locking mechanism 214 of an ALL are shown in FIG. 2. The VCO signal is first sampled by a digital sampler 210 and then divided by a divider 212 to generate the feedback signal, and then the feedback signal is compared with reference clock by a PFD 204. The output of the PFD will then control the charge pump and loop filter 206 to tune the VCO 208.

As shown in FIG. 2 214, within a certain frequency range, the frequency of the feedback signal can be treated as a linear function of the VCO frequency. The slope of the linear function within an ALL is ±1/N, where N is the division ratio of the feedback divider between the sampler 210 and the PFD 204. It should be mentioned that in an ALL, multiple VCO frequencies map to the same alias frequency. This disambiguation can be resolved by either initializing the CP with a digital-to-analog converter (DAC) fed from a lookup table or using two sampling frequencies to produce two alias frequencies to uniquely determine the targeting frequency as described in J. Liang, Z. Zhou, J. Han and D. G. Elliott, A 6.0-13.5 GHz Alias-Locked Loop Frequency Synthesizer in 130 nm CMOS, IEEE Transactions on Circuits and Systems I, vol. 60, no. 1, pp. 108-115, 2013.

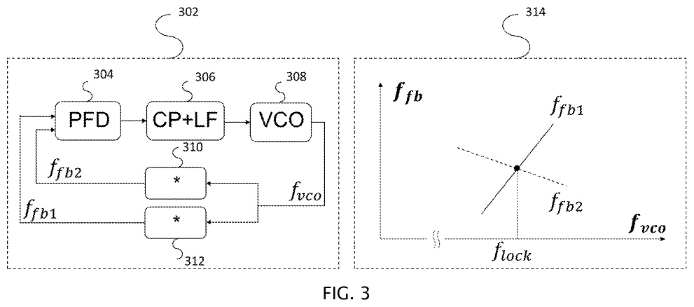

Instead of comparing a feedback signal with a fixed reference signal, two feedback signals with different slopes can be generated by two function blocks (represented by the two ‘*’ blocks 310 and 312 in FIG. 3. 302), fed into a PFD and compared with each other. The different slopes of the two feedback functions can provide a negative feedback of the loop and therefore ensure lock, as illustrated in FIG. 3 314. It should be mentioned that although a positive slope and a negative slope are illustrated in FIG. 3 314, any two unequal slopes (i.e. two unequal positive slopes, two unequal negative slopes, or one positive slope and one negative slope) could be used to achieve lock. In some embodiments, the feedback functional blocks represented by ‘*’ in FIG. 3 302 can be implemented by one or more digital samplers.

### Mathematical Preparations

Assuming a target VCO frequency f_{vco}=Rf_{S} is to be synthesized, where R is an arbitrary positive rational number and f_{S} is the sampling clock frequency. R can always be represented by the sum of a non-negative integer K and a non-negative proper fraction s; therefore we have,

R=K+s. (1)

It is easy to prove that there must exist a non-negative integer k₁ that can satisfy:

$$1 - \frac{1}{{2}^{{k}_{1}}} \leq s < 1 - \frac{1}{{2}^{{k}_{1} + 1}} . \qquad ( 2 )$$

Actually, if Equation (2) is not true, then for all the non-negative integers k₁, the following expression is correct:

$$s < 1 - \frac{1}{{2}^{{k}_{1}}} or s \geq 1 - \frac{1}{{2}^{{k}_{1} + 1}} . \qquad ( 3 )$$

Take k₁=0 for example, then we can obtain

s<0 or s≥½. (4)

Apparently s=¼ doesn't satisfy Equation (4), which proves the correctness of Equation (2).

Similarly, we can prove that there must exist a non-negative integer k₂ that can satisfy

$$\frac{1}{{2}^{{k}_{2} + 1}} < s \leq \frac{1}{{2}^{{k}_{2}}} . \qquad ( 5 )$$

It should be noted that s cannot be zero in Equation (5).

Assume the VCO frequency is f_{vco} and the sampling frequency is fₛ. Let f_{vco}/fₛ=R; then with Equations (1) and (2), it can be obtained that there must exist a non-negative integer k₁ that can satisfy

$$( 1 - \frac{1}{{2}^{{k}_{1}}} ) {f}_{s} \leq {f}_{vco} - {Kf}_{s} < ( 1 - \frac{1}{{2}^{{k}_{1} + 1}} ) {f}_{s} . \qquad ( 6 )$$

With simple algebraic manipulation, Equation (6) can be transformed to the following expression:

$$( {2}^{{k}_{1}} ( K + 1 ) - 1 ) \frac{{f}_{s}}{{2}^{{k}_{1}}} \leq {f}_{vco} < ( {2}^{{k}_{1}} ( K + 1 ) - 1 ) \frac{{f}_{s}}{{2}^{{k}_{1}}} + \frac{1}{2} \frac{{f}_{s}}{{2}^{{k}_{1}}} . \qquad ( 7 )$$

From Equation (7), it can be observed that if a sampling frequency fₛ/2^{k}^{₁} is used instead of fₛ, then the generated alias frequency is non-negative.

There must exist an integer D₁ that is no larger than 2^{k}^{₁} that can satisfy the following relationship:

$$( {D}_{1} ( K + 1 ) - 1 ) \frac{{f}_{s}}{{D}_{1}} \leq {f}_{vco} < ( {D}_{1} ( K + 1 ) - 1 ) \frac{{f}_{s}}{{D}_{1}} + \frac{1}{2} \frac{{f}_{s}}{{D}_{1}} . \qquad ( 8 )$$

Similarly, from Equations (1) and (5), there must exist a non-negative integer k₂ that can satisfy

$$( {2}^{{k}_{2}} K + 1 ) \frac{{f}_{s}}{{2}^{{k}_{2}}} - \frac{1}{2} \frac{{f}_{s}}{{2}^{{k}_{2}}} < {f}_{v c o} \leq ( {2}^{{k}_{2}} K + 1 ) \frac{{f}_{s}}{{2}^{{k}_{2}}} . \qquad ( 9 )$$

From Equation (9), it can be observed that if a sampling frequency fₛ/2^{k}^{₂} is used instead of fₛ, then the generated alias frequency is non-positive.

There must exist another integer D₂ that is no larger than 2^{k}^{₂} that can satisfy the following relationship:

$$( {D}_{2} K + 1 ) \frac{{f}_{s}}{{D}_{2}} - \frac{1}{2} \frac{{f}_{s}}{{D}_{2}} < {f}_{v c o} \leq ( {D}_{2} K + 1 ) \frac{{f}_{s}}{{D}_{2}} . \qquad ( 10 )$$

If two derived frequencies intersect at a VCO frequency, then these can be used to control a negative feedback loop. For the generated alias frequencies, such intersections will only occur if one alias frequency is positive and one alias frequency is negative. Since these numbers such as 2^{k}^{₁}, 2^{k}^{₂}, D₁, and D₂, are used to determine the division ratios of the sampling clocks, they are named sampling clock division ratios.

### Differential Alias-Locked Loops

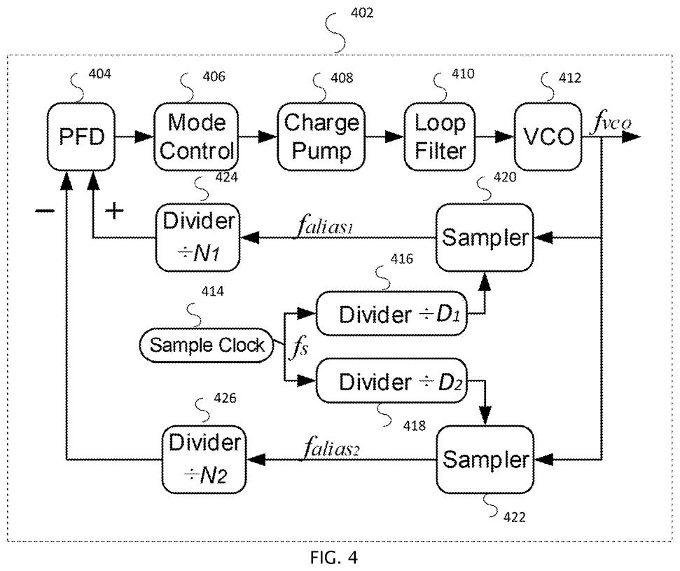

One possible embodiment of the frequency synthesizer with the locking mechanism described in FIG. 3 314 could be a differential alias-locked loop. For a targeted VCO frequency f_{vco}, by properly selecting the sampling clock division ratios (D₁ and D₂), both positive alias frequency and negative alias frequency can be generated simultaneously with two samplers. Based on the locking mechanism proposed in FIG. 3 314, as long as neither of the two alias frequencies is 0, a PFD can be applied to compare the two divided alias frequencies and eventually bring the loop into lock. Since the two signals feeding into the PFD are equal in frequency but opposite in polarity when in lock, this architecture is named a differential alias-locked loop (D-ALL). One possible implementation of a D-ALL is illustrated in FIG. 4 402.

Instead of using only one sampler in an ALL in FIG. 2 210, a D-ALL has two sampling paths with two samplers 420 and 422 and the generated alias frequencies are fed in a PFD 404. One of the two alias frequencies must be negative while the other must be positive.

Similar to an ALL architecture, a change in frequency could cause a change in sign in the alias frequency; the loop feedback could then switch from negative to positive. The mode-control module 406, which is usually implemented with multiplexers, can invert the sense of the PFD 404 output as needed by swapping the two PFD outputs feeding the CP 408 to keep the loop feedback negative over the whole range of frequencies where D-ALL frequency lock may be obtained. Therefore, a D-ALL will be functional only with the correct selection of:
Sampling clock division ratios of D₁ and D₂ of dividers 416 and 418;
Alias divider ratios of N₁ and N₂ of dividers 424 and 426;
Loop polarity by controlling the mode-control module 406.

Calibrations are usually needed in digital samplers due to DC offset introduced by process variations. A digital sampler usually contains the sampler itself together with calibration modules. It can be observed that two samplers 420 and 422 are required in FIG. 4 402 which therefore means two separate calibration modules.

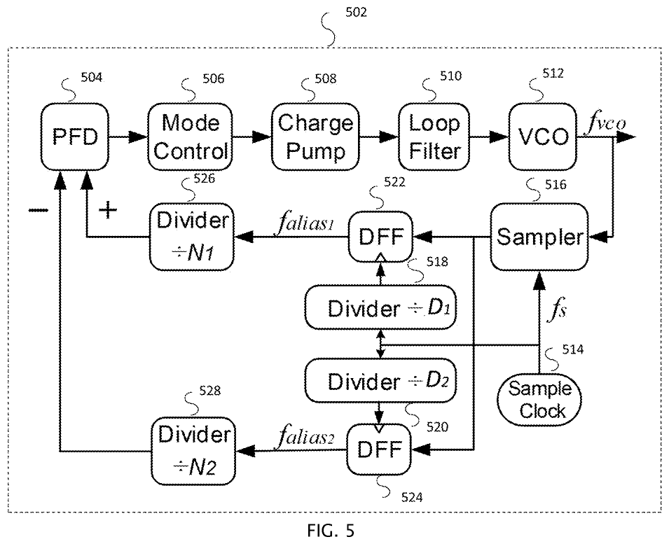

FIG. 5 502 presents another possible implementation of a D-ALL that uses only one digital sampler 516 clocking at fₛ, generating the alias signal with a sampling clock 514 at frequency of fₐₗᵢₐₛ. The two differential signals fₐₗᵢₐₛ₁ and fₐₗᵢₐₛ₂, are generated by re-sampling of fₐₗᵢₐₛ with two latches, i. e. D-type Flip Flops (DFFs) 520 and 522 clocking at

$$\frac{{f}_{s}}{{D}_{1}} and \frac{{f}_{s}}{{D}_{2}} ,$$

respectively.

The architecture shown in FIG. 5 502 is mathematically equivalent to that shown in FIG. 4 402 but with only one high-speed digital sampler 516 connected to the VCO 512 instead of two, which can save area, power consumption, and matching requirements The digital sampler 516 can be implemented with a sense-amplifier style differential latch or a CML latch, which can save silicon area compared to an LC-oscillator-based injection locked frequency divider in a conventional high-frequency PLL in J. Lee, M. Liu and H. Wang, A 75-GHz Phase-Locked Loop in 90-nm CMOS Technology, in IEEE journal of Solid-State Circuits, vol. 43, no. 6, pp. 1414-1426, June 2008.

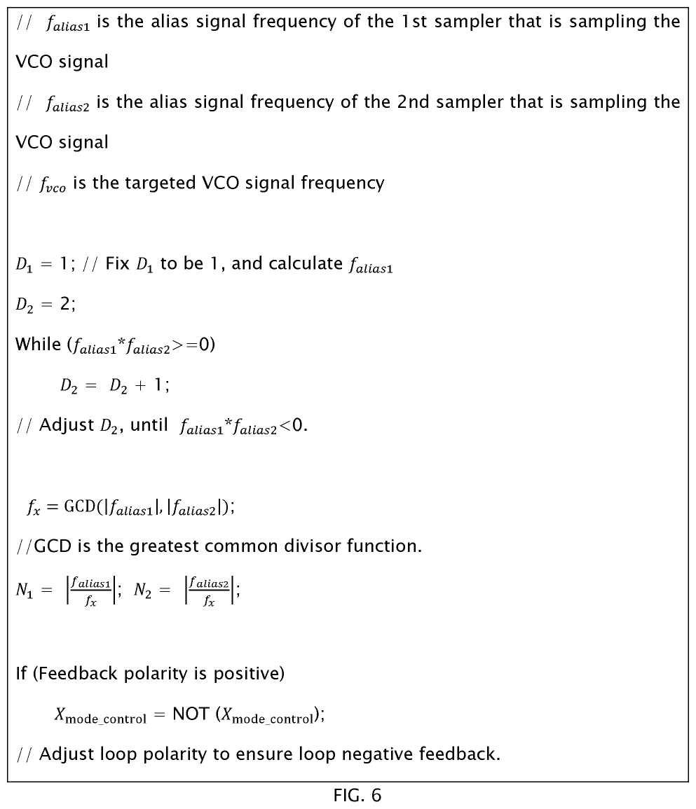

The design procedures of the D-ALL in FIG. 4 402 are summarized in FIG. 6. Take, for example, a targeted frequency of f_{vco}=21.8 GHz and a sampling frequency of fₛ=1 GHz:
First set D₁=1, and use fₛ=1 GHz directly as the first sampling clock; thus the targeting alias frequency is fₐₗᵢₐₛ₁=−200 MHz;
Starting from 2, keep increasing D₂ by 1 each time, until fₐₗᵢₐₛ₂>0. In this example, when D₂=2, we have fₛ₂=0.5 GHz and fₐₗᵢₐₛ₂=−200 MHz which cannot satisfy the relationship; when D₂=3, we have fₛ₂=0.333 GHz and fₐₗᵢₐₛ₂=+133 MHz which can satisfy the relationship;
By choosing N₁=3 and N₂=2, the relationship of

$$\vert \frac{{f}_{a l i a s 1}}{{N}_{1}} \vert = \vert \frac{{f}_{a l i a s 2}}{{N}_{2}} \vert$$

can be satisfied;
Determine the value of X_{mode_control} by examining the loop polarity.

FIG. 6 can also be used as the design procedures of the D-ALL in FIG. 5 502.

### ANALYSIS AND DISCUSSIONS

### Frequency Acquisitions

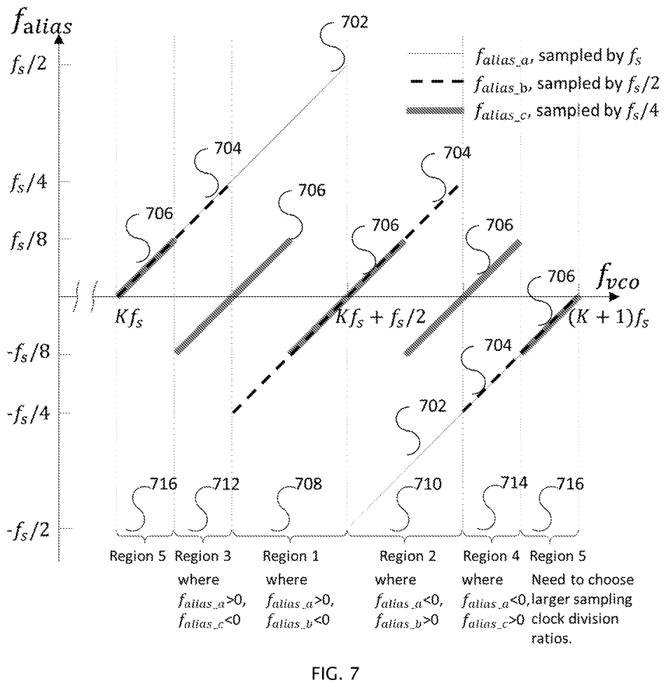

FIG. 7 shows the alias frequencies produced by a D-ALL. f_{VCO} represents the VCO input frequency, fₛ represents the input sampling frequency, f_{alias_a} 702, f_{alias_b} 704 and f_{alias_c} 706 represent the output alias frequencies corresponding to the sampling frequencies of fₛ, fₛ/2, and fₛ/4 respectively. The shadows show the different operation regions of the D-ALL.

If the desired VCO frequency is within ‘Region1’ 708 (or ‘Region2’ 710), then by setting D₁=1 and D₂=2 (or D₁=2 and D₂=1), we can have a positive alias frequency f_{alias_a} 702 (or f_{alias_b} 704) and a negative alias frequency=f_{alias_b} 704 (or f_{alias_a} 702). Similarly, if the desired VCO frequency is within ‘Region3’ 712 (or ‘Region4’ 714), then by setting D₁=2 and D₂=4 (or D₁=4 and D₂=2), we can have a positive alias frequency f_{alias_b} 704 (or f_{alias_c} 706) and a negative alias frequency f_{alias_c} 706 (or f_{alias_b} 704). If the desired VCO frequency is within ‘Region5’ 716, in order to generate a positive alias frequency and a negative alias frequency, then larger D₁ and D₂ values need to be selected to provide different sampling frequencies.

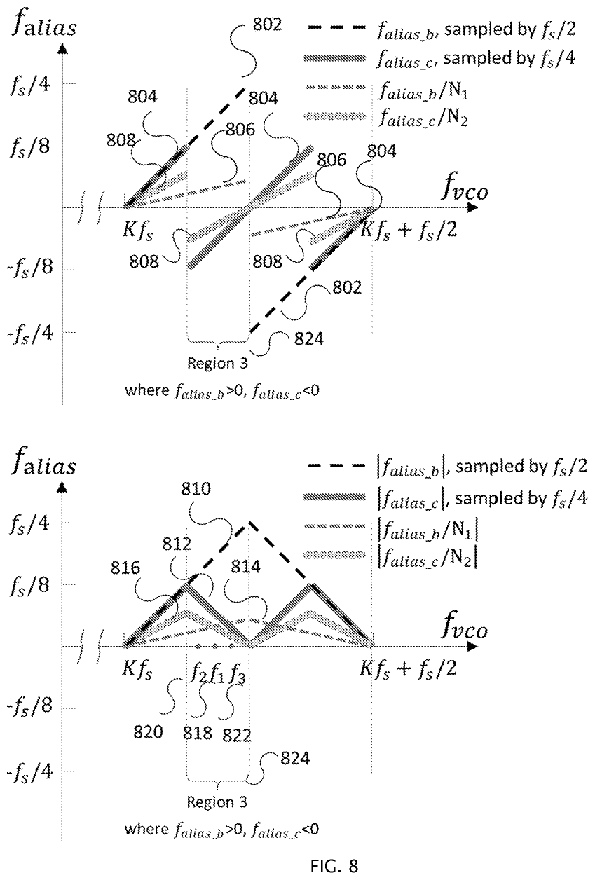

The acquisition and lock operation is illustrated in FIG. 8. Assume f₁ 818, f₂ 820, and f₃ 822 are three frequencies in the same region (i.e. ‘Region3’ 824 in FIG. 8), where f₁ 818 is the desired frequency, f₂ 820 is smaller than f₁ 818, and f₃ 822 is larger than f₁ 818. Since f_{vco}=f₁ is the desired output frequency, the division ratios N₁ and N₂ are set to satisfy the following equation when f_{vco}=f₁:

$$\vert \frac{{f}_{alias\_b}}{{N}_{1}} \vert = \vert \frac{{f}_{alias\_c}}{{N}_{2}} \vert . \qquad ( 11 )$$

According to FIG. 8, in ‘Region3’ 824, f_{alias_b} 802 is positive while f_{alias_c} 804 is negative. Assume the VCO frequency is initialized to be f₂ 820 by additional modules such as a frequency-locked loop (FLL) or a digital-to-analog converter (DAC). It can be seen that If |f_{alias_b}/N₁| 814 is smaller than |f_{alias_c}/N₂| 816 when f_{vco}=f₂. The frequency difference is compared by a PFD and then the LF voltage is tuned by the CP to increase the VCO frequency. Similarly, if the initialized frequency is f_{vco}=f₃, then |f_{alias_b}/N₁| 814 is larger than |f_{alias_c}/N₂| 816, which will decrease the VCO frequency.

The D-ALL is a negative feedback loop in ‘Region3’ 824 and will eventually achieve lock at f_{vco}=f₁ 818 by satisfying |f_{alias_b}/N₁| 814 and |f_{alias_c}/N₂| 816. By switching the values of D₁ and D₂, or simply changing the loop polarity with the mode-control module 406 in FIG. 4 or the mode-control module 506 in FIG. 5, the same analysis will result in a negative feedback loop for the D-ALL in another different region (i.e. ‘Region4’ 714 in FIG. 7) and another targeting frequency in ‘Region4’ 714 can be synthesized.

It can also be observed from FIG. 7 that with sampling clock division ratios (i.e., D₁ and D₂) increasing, the corresponding frequency acquisition range (i.e., ‘Region1’ 708, ‘Region2’ 710, ‘Region3’ 712 and ‘Region4’ 714) is becoming smaller. This imposes more stringent requirements of the other modules, such as a higher-resolution DAC to initialize the VCO into the correct frequency range. Therefore, although infinite pairs of (D₁, D₂) are available to satisfy the D-ALL requirement, minimum possible values of (D₁, D₂)ₘₐₓ are preferred in a D-ALL.

### Frequency Resolutions

Channel bandwidth in communication systems determines the frequency resolution of the frequency synthesizers. For instance, Bluetooth has a channel bandwidth of 1 MHz; therefore the frequency resolution of a Bluetooth frequency synthesizer is 1 MHz. In advanced high-speed wireless communication systems such as the 5G communication network, the channel bandwidth is undoubtedly high because of the high speed. For instance, a 100 MHz channel bandwidth in the 28 GHz frequency band is discussed in 5G Spectrum Recommendations, August 2015, (Online access: http://www.4gamericas.org/files/6514/3930/9262/4G_Americas_5 G_Spectrum_Recommendations_White_Paper.pdf).

For a D-ALL, as long as f_{alias_b}*f_{alias_c}<0 and

$$\vert \frac{{f}_{alias\_b}}{{N}_{1}} \vert = \vert \frac{{f}_{alias\_c}}{{N}_{2}} \vert$$

can be satisfied, the loop can be locked by properly choosing N₁ and N₂.

Theoretically, a D-ALL can achieve arbitrarily small frequency resolutions by programming the divider ratios N₁ and N₂. Unfortunately, N₁ and N₂ cannot be arbitrarily large as discussed below.

In a traditional PLL, the bandwidth of the loop is usually determined by minimizing the total phase noise, which is the frequency offset for which the in-band phase noise equals the out-of-band phase noise. In a D-ALL, when N₁ and N₂ are large,

$$\vert \frac{{f}_{alias\_b}}{{N}_{1}} \vert ( and also \vert \frac{{f}_{alias\_c}}{{N}_{2}} \vert )$$

will be small and the output of the PFD will be at a low frequency. To satisfy the continuous loop approximation requirement, the bandwidth of the loop should be around or smaller than

$$\frac{1}{10} \vert \frac{{f}_{alias\_b}}{{N}_{1}} \vert ,$$

and therefore cannot be the optimal bandwidth at which the phase noise is minimized.

### Number of Reference Clocks

One limitation of the ALL architecture lies in the requirement of one additional clock. Instead of using only one reference clock in a conventional PLL, two clocks are required in an ALL, with one for sampling and the other as a reference clock. Based on the proposed differential locking mechanism, a D-ALL has solved this problem by eliminating the reference clock.

One potential issue is that the sampling clock usually needs to have a high frequency, i.e. 1 GHz. However, a 1 GHz sampling clock is usually not directly available from a crystal oscillator. Fortunately, there are various low-cost architectures to achieve a 1 GHz signal with low jitter (i.e., an RMS jitter less than 3 ps). In addition to the conventional PLLs, multiple low-cost low-phase noise approaches have been proposed in the last decade, including the multiplying delay-locked loop (MDLL) in Farjadrad R, Dally W J, Ng H, et al. A low-power multiplying DLL for low-jitter multi-gigahertz dock generation in highly integrated digital chips IEEE journal of Solid-state Circuits, 2002, 37(12): 1804-1812, injection-locked LC-VCO in Elshazly A, Inti R, Young B, et al. Clock Multiplication Techniques Using Digital Multiplying Delay-Locked Loops, IEEE journal of Solid-state Circuits, 2013, 48(6): 1416-1428, subsampling PLL (SSPLL) in X. Gao, E. A. M. Klumperink, M. Bohsali and B. Nauta, A Low Noise Sub-Sampling PLL in Which Divider Noise is Eliminated and PD/CP Noise is Not Multiplied by N² in IEEE journal of Solid-State Circuits, vol. 44, no. 12, pp. 3253-3263, December 2009. and injection-locked ring oscillator (ILRO) in Chien J, Lu L. Analysis and Design of Wideband Injection-Locked Ring Oscillators With Multiple-Input Injection IEEE journal of Solid-state Circuits, 2007, 42(9): 1906-1915. Take the ILRO as an example. With a simple architecture, ILRO can low-pass filter the noise from the injection clock and high-pass filter the noise from the ring oscillator, which functions similar to a conventional PLL. Measurements have shown that for a targeted 2.5 GHz signal, the RMS jitter is smaller than 5 ps in most cases and can be smaller than 1.5 ps when tuning the bandwidth of the ILRO.

### Loop Bandwidth

The conventional PFD operates in discrete-time, and the continuous-time approximation requires that the loop time constant be much longer than the input period; therefore, we have:

$${ω}_{- 3 dB , D - ALL} ≪ \frac{2 π {f}_{alias 1}}{{N}_{1}} , \qquad ( 12 )$$

where ω_{-3 dB} is the loop bandwidth.

For a certain range of desired frequencies, fₐₗᵢₐₛ₁/N₁ varies for different f_{vco}. To meet the requirement of Equation (12), the loop bandwidth is set to satisfy:

$${ω}_{- 3 dB , D - ALL} \leq \frac{1}{10} {( \frac{2 π {f}_{alias 1}}{{N}_{1}} )}_{min} . \qquad ( 13 )$$

It should be noted that the relationship in Equation (13) is much different from the relationship of a conventional PLL,

$${ω}_{- 3 dB , PLL} \leq \frac{1}{10} ( 2 π {f}_{ref} ) = \frac{1}{10} ( \frac{2 π {f}_{VCO}}{{N}^{′}} ) , \qquad ( 14 )$$

where

$$\frac{2 π {f}_{VCO}}{{N}^{′}}$$

is usually determined by the frequency resolution in an integer-N PLL.

Assume a targeting frequency range of 21.6-21.9 GHz to be synthesized with a frequency step of 100 MHz (21.6 GHz, 21.7 GHz, 21.8 GHz and 21.9 GHz) with a sampling frequency of 1 GHz.
For 21.9 GHz, we can set D₁=1 to have a 1 GHz sampling clock and fₐₗᵢₐₛ₁=−100 MHz, D₂=6 to have a 166.7 MHz sampling clock and fₐₗᵢₐₛ₂=66.7 MHz, and then we can set N₁=3 and N₂=2 to satisfy Equation (11).
For 21.8 GHz, we can set D₁=1 to have a 1 GHz sampling clock and fₐₗᵢₐₛ₁=−200 MHz, D₂=3 to have a 333.3 MHz sampling clock and fₐₗᵢₐₛ₂=133.4 MHz, and then we can set N₁=3 and N₂=2 to satisfy Equation (11).
For 21.7 GHz, we can set D₁=1 to have a 1 GHz sampling clock and fₐₗᵢₐₛ₁=−300 MHz, D₂=2 to have a 500 MHz sampling clock and fₐₗᵢₐₛ₂=200 MHz, and then we can set N₁=3 and N₂=2 to satisfy Equation (11).
For 21.6 GHz, we can set D₁=1 to have a 1 GHz sampling clock and fₐₗᵢₐₛ₁=−400 MHz, D₂=2 to have a 500 MHz sampling clock and fₐₗᵢₐₛ₂=100 MHz, and then we can set N₁=4 and N₂=1 to satisfy Equation (11).

Therefore,

$${ω}_{- 3 dB , D - ALL} \leq \frac{1}{10} {( \frac{2 π {f}_{alias 1}}{{N}_{1}} )}_{min} = \frac{2 π}{10} * Min ( 33.3 , 66.6 , 100 , 100 ) \\ MHz = \frac{2 π}{10} * 33.3 MHz = 2 π * 3.3 MHz \qquad ( 15 )$$

For an integer-N PLL with a reference frequency of 100 MHz,

ω_{-3 dB,PLL}≤ 1/10(2πf_{ref})=2π*10 MHz. (16)

Therefore, for this example, the required loop bandwidth of a D-ALL is smaller than an integer-N PLL.

### Design and Simulation Results

To verify the D-ALL architecture 502 as shown in FIG. 5, a 21-23.3 GHz D-ALL was designed using GlobalFoundries 130 nm Bulk CMOS process and post-layout extracted circuit simulations were performed in Cadence Spectre.

LC VCO: a 21-23.3 GHz LC VCO is designed. The VCO is tuned with varactors and two binary-weighted switched capacitors, which extend the tuning rage (21 GHz-23.3 GHz) without increasing the K_{VCO} of the VCO (K_{VCO} is ˜614 MHz/V in the middle range).

Sampler: a CML latch is used to sample the 21-23.3 GHz VCO, and buffers are inserted between the VCO and sampler to reduce the effects of the act of sampling from loading the VCO.

Sampling clock buffer: a buffer is designed to ensure the rising edge clean. By re-positioning the triggered edges for the NMOS and the PMOS, short-circuit current can be avoided and a clean sharp rising edge can be therefore achieved.

Digital blocks: the digital blocks contain the re-sampling DFFs, the programmable dividers for alias signals, and the programmable dividers for the sampling clocks, and the block is synthesized by standard digital synthesis.

Other modules: the PFD is implemented with the conventional architecture, and a fully differential topology has been used in the CP design to reduce the effect of the non-idealities of the CP transistors. The mode-control module is designed to selectively invert the sense of lead and lag to ensure the loop always negative feedback.

Layout considerations: multiple power domains have been used to reduce the noise coupled from the power and ground signal lines. Additionally, the sampler is placed in a triple-well to reduce the substrate coupled noise from the other modules.

Simulations: the D-ALL was verified through a post-layout extracted circuit simulation using Cadence. D-ALL synthesizer pull-in and lock were demonstrated at 6 frequencies (21.6 GHz, 21.7 GHz, 21.8 GHz, 21.9 GHz, 22.3 GHz, and 22.4 GHz) throughout the VCO range of 21-23.3 GHz. Simulations are run with full transistor noise models at 27° C. Assume a 21.6 GHz output signal is desired to be synthesized and a fₛ=1 GHz signal is available as the sampling clock. By setting the sampling clock division ratios to be D₁=1, D₂=2, and alias divider ratios to be N₁=4 and N₂=1, then the sampling clock for the first sampler is 1 GHz and the corresponding alias frequency when the loop is in lock is fₐₗᵢₐₛ₁=−400 MHz, while the sampling clock for the second sampler is 500 MHz and the corresponding alias frequency when the loop is in lock is fₐₗᵢₐₛ₂=+100 MHz. Then the divided frequencies feeding into the PFD are

$$\frac{{f}_{a l i a s 1}}{{N}_{1}} = \frac{- 4 \; 00 MHz}{4} = - 1 \; 00 MHz and$$

$$\frac{{f}_{alias 2}}{{N}_{2}} = \frac{+ 100}{1} = + 1 \; 00 MHz$$

respectively, which can therefore maintain the lock.

Assume the initialized VCO frequency is 21.7 GHz. With the above settings, the alias frequencies are

$${f}_{alias 1} = - 3 \; 00 MHz , {f}_{alias 2} = + 2 \; 00 MHz and$$

$$\frac{{f}_{a l i a s 1}}{{N}_{1}} = \frac{- 300}{4} = - 75 MHz , \frac{{f}_{a l i a s 2}}{{N}_{2}} = \frac{+ 200}{1} = + 2 \; 00 MHz .$$

Feeding the −75 MHz signal and the +200 MHz signal into the PFD will decrease the VCO frequency until the loop is in lock.

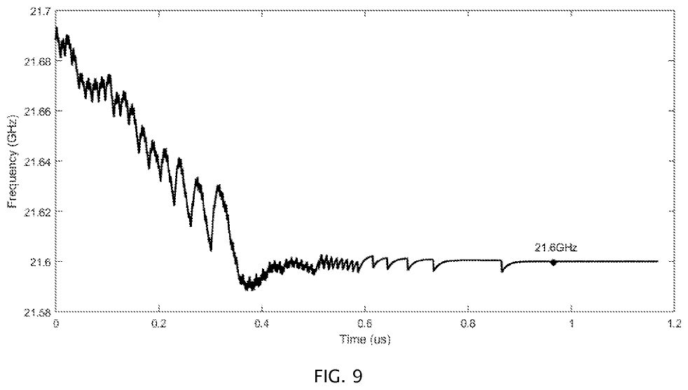

The D-ALL was verified through a post-layout extracted circuit simulation using Cadence Spectre. A 1 GHz square wave is used as the sampling clock. Simulation has shown that the designed D-ALL can synthesize multiple targeted frequencies. Transient simulation results of synthesizing the targeted 21.6 GHz signal are illustrated in FIG. 9.

In a conventional high-frequency PLL, dividers are usually the most power-hungry modules since multiple stages are required and DC bias is needed in each of the first few high-speed stages. For instance, in Y. Ding and K. K. O, A 21-GHz 8-Modulus Prescaler and a 20-GHz Phase-Locked Loop Fabricated in 130-nm CMOS in IEEE Journal of Solid-State Circuits, vol. 42, no. 6, pp. 1240-1249, June 2007, a PLL with a 21 GHz maximum operating frequency was implemented in 130 nm Bulk CMOS process. The total power consumption is 22.5 mW, of which 9 mW is dissipated by the divider chain including the CML prescaler. In the D-ALL architecture, however, the total power consumption is 15.4 mW, of which only 2.9 mW is dissipated by the digital sampler, which is 67.8% less. The active area of the above-mentioned conventional PLL is 0.28 mm², while in the case of the designed D-ALL, the active area is 0.21 mm².

Another advantage of a sampler over a divider is that the sampler simultaneously allows a high operation frequency and a wide frequency range. Although the D-ALL is verified to synthesize a frequency range of 21-23.3 GHz, additional simulation has shown that the digital sampler can function for frequencies as high as 40 GHz and a range from almost DC to 40 GHz. This is different from the conventional dividers since a digital sampler only needs to make a sampling “decision” at the 1 GHz sampling clock rate, while a divider has to be clocked at the 40 GHz VCO rate.

As will be apparent to those skilled in the art, various modifications, combinations and adaptations of the specific embodiment, method and examples herein are possible without departing from the present invention. The invention should therefore not be limited by the above described embodiment, method, and examples, but by all embodiments and methods within the scope and spirit of the invention as claimed.

What is claimed is:

1. A phase-locked loop, comprising:
a. a phase detector having as inputs two feedback signals, the phase detector being operable to generate a phase detection signal based on a comparison of phases between the two feedback signals;
b. an optional mode control module coupled to the phase detector to adjust the loop polarity to ensure the loop negative feedback;
c. an optional loop filter coupled to the phase detector for receiving the phase detection signal and for generating an output voltage in response to the phase detection signal;
d. a tunable oscillator coupled to the output of the loop filter for generating an oscillator signal;
e. A feedback module with two or more feedback signals, one or more of these feedback signals operating at a reduced frequency generated from the oscillator signal, and the frequencies of these feedback signals having different slopes with respect to the oscillator frequency.

2. The phase-locked loop of claim 1, wherein the feedback module, one or more regenerative sampling latches are incorporated to generate the feedback signals. The regenerative sampling latches operate as frequency reduction circuits by sampling the oscillator signal. The frequency of each regenerative sampling latch output signal averages to an alias frequency that is determined by the corresponding sampling signal frequency and oscillator frequency, respectively.

3. The phase-locked loop of claim 2, wherein only one regenerative sampling latch is incorporated in the feedback module, the regenerative sampling latch is clocked by a separate sampling clock signal at frequencies lower than the oscillator frequency.

4. The phase-locked loop of claim 3, where two or more latches are incorporated in cascade with the regenerative sampling latch, respectively.

5. The phase-locked loop of claim 4, where the clocks for the latches can be generated by dividing the sampling clock signal of the regenerative sampling latch, and the division ratios can be any positive integer.

6. The phase-locked loop of claim 4, where frequency dividers can be incorporated in cascade with the latches to adjust the frequency and phase of the feedback signals. The division ratios can be any positive number.

7. The phase-locked loop of claim 2, wherein two or more regenerative sampling latches are incorporated in the feedback path, the regenerative sampling latches are clocked by separate sampling clock signals at frequencies lower than the oscillator frequency.

8. The phase-locked loop of claim 7, where the sampling clock signals for the regenerative sampling latches can be generated by dividing the same clock signal. The division ratios can be any positive number.

9. The phase-locked loop of claim 7, where frequency dividers can be incorporated in cascade with the regenerative sampling latches to adjust the frequency and phase of the feedback signals. The division ratios can be any positive number.

10. The phase-locked loop of claim 2, where each regenerative sampling latch can further comprise separate input that allows for adjustment of the input switching threshold.

11. The phase-locked loop of claim 2, where each regenerative sampling latch can be coupled to a duty-cycle measurement circuit that evaluates the duty cycle of the regenerative sampling latch output signal.

12. The phase-locked loop of claim 2, where each regenerative sampling latch can comprise a separate input that allows for the adjustment of the switching threshold and where said input switching threshold adjustment controls are coupled to a duty-cycle measurement circuit at the output of the regenerative sampling latch.

13. The phase-locked loop of claim 1, where the mode control module can comprise:
a. a multiplexer coupled between the outputs of the feedback module and the phase detector, wherein one multiplexer input coupled to the first output signal of the feedback module, and the other multiplexer input coupled to the second output signal of the feedback module, while the output of the multiplexer coupled to the first input of the phase detector;
b. another multiplexer coupled between the outputs of the feedback module and the phase detector, wherein one multiplexer input coupled to the second output signal of the feedback module, and the other multiplexer input coupled to the first output signal of the feedback module, while the output of the multiplexer coupled to the second input of the phase detector;
c. a digital control signal coupled to the controlling inputs of the two multiplexers, wherein when the digital control signal is ‘1’ (or ‘0’), the output of the first multiplexer is the first output signal of the feedback module, and the output of the second multiplexer is the second output signal of the feedback module; and when the digital control signal is ‘0’ (or ‘1’), the output of the first multiplexer is the second output signal of the feedback module, and the output of the second multiplexer is the first output signal of the feedback module.

14. The phase-locked loop of claim 1, wherein the feedback module, one regenerative sampling latch is incorporated into a feedback path. The regenerative sampling latch operate as frequency reduction circuits by sampling the oscillator signal. The frequency of the regenerative sampling latch output signal averages to an alias frequency that is determined by the corresponding sampling signal frequency and oscillator frequency, respectively.

15. A control system where one or more inputs to the system are controlled to minimize the difference between multiple signals generated from the system state.

16. The control system in claim 15, where the control system has 1 input and the difference between 2 signals generated from the system state are minimized.

17. The control system in claim 16, where the 2 signals compared have different slopes with respect to the system input.

18. The control system in claim 16, where the slopes of the 2 signals compared have different signs with respect to the system input.

19. The control system in claim 16, where the frequencies of the 2 signals are compared.

20. The control system in claim 16, where the phases of the 2 signals are compared.

21. The control system in claim 15, where the frequencies of signals generated from the system state are compared.

22. The control system in claim 15, where the phases of signals generated from the system state are compared.
